(19) United States
(12) Patent Application Publication
(10) Pub. No.: US 2024/0145656 A1
(43) Pub. Date: May 2, 2024

(54) DISPLAY DEVICE AND METHOD OF MANUFACTURING THE SAME

(71) Applicant: LG Display Co., Ltd., Seoul (KR)

(72) Inventors: YoungIn JANG, Seoul (KR); Soyoung LEE, Seoul (KR); HyunGon KIM, Seoul (KR)

(73) Assignee: LG Display Co., Ltd., Seoul (KR)

(21) Appl. No.: 18/386,363

(22) Filed: Nov. 2, 2023

(30) Foreign Application Priority Data
Nov. 2, 2022 (KR) 10-2022-0144590

(51) Int. Cl. H01L 33/62; H01L 25/16; H01L 33/60

(52) U.S. Cl. CPC H01L 33/62; H01L 25/167; H01L 33/60; H01L 2933/0066

(57) ABSTRACT

According to an aspect of the present disclosure, a display device includes: a substrate on which a plurality of sub-pixels is defined; a light-emitting element disposed on each of the plurality of sub-pixels and having an inversely tapered shape; a first connection electrode configured to surround a side surface of a lower portion of the light-emitting element; a second connection electrode configured to cover an upper portion of the light-emitting element; and a first planarization layer disposed between the first connection electrode and the second connection electrode. Therefore, the first connection electrode, which surrounds a lower portion of the light-emitting element, may be formed to be spaced apart from an upper portion of the light-emitting element by using the light-emitting element having an inversely tapered shape.

### CROSS-REFERENCE TO RELATED APPLICATIONS

This application claims the priority of Korean Patent Application No. 10-2022-0144590 filed on Nov. 2, 2022, in the Korean Intellectual Property Office, the disclosure of which is incorporated herein by reference.

### BACKGROUND

### Technical Field

The present specification relates to a display device and a method of manufacturing the same, and more particularly, to a display device, which uses a light-emitting diode (LED), and a method of manufacturing the same.

### Discussion of the Related Art

As display devices used for a monitor of a computer, a TV set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED may be quickly turned on or off, have excellent luminous efficiency, high impact resistance, and great stability, and display high-brightness images.

### SUMMARY

Accordingly, embodiments of the present disclosure are directed to a display device and a method of manufacturing the same that substantially obviate one or more of the problems due to limitations and disadvantages of the related art.

An aspect of the present disclosure is to provide a display device, in which a first connection electrode and a first semiconductor layer of a light-emitting element may be self-aligned, and a method of manufacturing the same.

Another aspect of the present disclosure is to provide a display device, in which a second connection electrode and a second semiconductor layer of a light-emitting element may be self-aligned, and a method of manufacturing the same.

Still another aspect of the present disclosure is to provide a display device, which minimizes a short-circuit defect occurring when a position at which a first connection electrode is formed and a position at which a second connection electrode is formed are misaligned by a process error, and a method of manufacturing the same.

Yet another aspect of the present disclosure is to provide a display device, which has improved light extraction efficiency, and a method of manufacturing the same.

Still yet another aspect of the present disclosure is to provide a display device, in which a light-emitting element has an inversely tapered shape, and a first semiconductor layer of the light-emitting element and a first connection electrode are connected in a self-alignment manner, or a second semiconductor layer and a second connection electrode are connected in a self-alignment manner, and a method of manufacturing the same.

A further aspect of the present disclosure is to provide a display device, in which a light-emitting element is transferred in a self-assembling manner to simplify a process, and a method of manufacturing the same.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises: a substrate on which a plurality of sub-pixels is defined; a light-emitting element disposed on each of the plurality of sub-pixels and having an inversely tapered shape; a first connection electrode configured to surround a side surface of a lower portion of the light-emitting element; a second connection electrode configured to cover an upper portion of the light-emitting element; and a first planarization layer disposed between the first connection electrode and the second connection electrode. Therefore, the first connection electrode, which surrounds a lower portion of the light-emitting element, may be formed to be spaced apart from an upper portion of the light-emitting element by using the light-emitting element having an inversely tapered shape.

In another aspect, a method of manufacturing a display device comprises: transferring a light-emitting element having an inversely tapered shape onto a bonding layer; forming a first connection electrode by forming a metallic material layer on the light-emitting element; forming a first planarization layer on the light-emitting element and the first connection electrode, the first planarization layer having a larger thickness than a first semiconductor layer of the light-emitting element; and forming a second connection electrode on the first planarization layer and the light-emitting element. Therefore, the light-emitting element having an inversely tapered shape may be used to connect the first connection electrode only to the first semiconductor layer disposed below the light-emitting element in a self-alignment manner, and the first planarization layer may be used to connect the second connection electrode only to the second semiconductor layer disposed above the light-emitting element in a self-alignment manner.

Other detailed matters of the exemplary embodiments are included in the detailed description and the drawings.

According to the present specification, the light-emitting element has an inversely tapered shape, and the metallic material layer on the light-emitting element is disconnected, such that the first connection electrode, which is electrically connected only to the first semiconductor layer disposed below the light-emitting element, may be formed.

According to the present specification, the first planarization layer is formed to cover the first semiconductor layer and the light-emitting layer, such that the second connection electrode and the second semiconductor layer may be self-aligned and formed.

According to the present specification, the first connection electrode and the second connection electrode may be easily formed in a self-alignment manner.

According to the present specification, the first connection electrode and the second connection electrode are respectively self-aligned with the first semiconductor layer and the second semiconductor layer of the light-emitting element, which may minimize a short-circuit defect caused by a forming error of the first and second connection electrodes.

According to the present specification, the reflective electrode is formed below the light-emitting element, which may improve light extraction efficiency.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a schematic configuration view of a display device according to an exemplary embodiment of the present specification;

FIG. 2A is a partial cross-sectional view of the display device according to the exemplary embodiment of the present specification;

FIG. 2B is a perspective view of a tiling display device according to the exemplary embodiment of the present specification;

FIG. 3 is a cross-sectional view of a sub-pixel of the display device according to the exemplary embodiment of the present specification;

FIGS. 4A to 4C are process diagrams for explaining a method of manufacturing a light-emitting element of the display device according to the exemplary embodiment of the present specification;

FIGS. 5A to 5D are process diagrams for explaining a self-assembling method of assembling the light-emitting element of the display device according to the exemplary embodiment of the present specification;

FIGS. 6A to 6D are process diagrams for explaining a process of forming a first connection electrode and a second connection electrode of the display device according to the exemplary embodiment of the present specification;

FIG. 7 is a cross-sectional view of a display device according to another exemplary embodiment of the present specification;

FIGS. 8A to 8C are process diagrams for explaining a method of manufacturing the display device according to another exemplary embodiment of the present specification;

FIG. 9 is a cross-sectional view of a display device according to still another exemplary embodiment of the present specification;

FIGS. 10A to 10D are process diagrams for explaining a method of manufacturing the display device according to still another exemplary embodiment of the present specification;

FIG. 11 is a cross-sectional view of a display device according to yet another exemplary embodiment of the present specification; and

FIG. 12 is a cross-sectional view of a display device according to still yet another exemplary embodiment of the present specification.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings

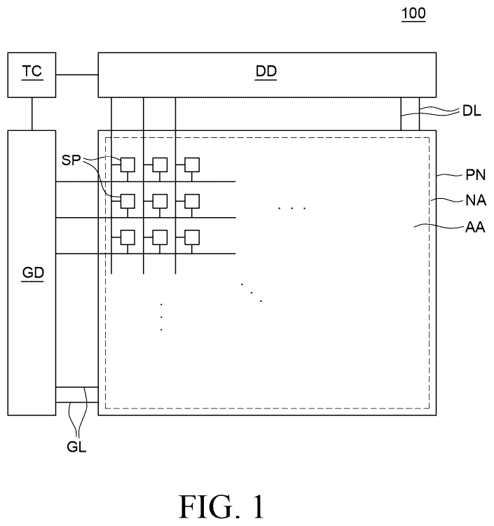

FIG. 1 is a schematic configuration view of a display device according to an exemplary embodiment of the present specification. For convenience of description, FIG. 1 illustrates only a display panel PN, a gate drive part GD, a data drive part DD, and a timing controller TC among various constituent elements of a display device 100.

With reference to FIG. 1, the display device 100 includes the display panel PN including a plurality of sub-pixels SP, the gate drive part GD configured to supply various types of signals to the display panel PN, and the timing controller TC configured to control the data drive part DD, the gate drive part GD, the data drive part DD.

The gate drive part GD supplies a plurality of scan signals to a plurality of gate lines GL in response to a plurality of gate control signals provided from the timing controller TC. FIG. 1 illustrates that the single gate drive part GD is disposed to be spaced apart from one side of the display panel PN. However, the number of and arrangement of the gate drive part GD are not limited thereto.

The data drive part DD converts image data, which are inputted from the timing controller TC, into a data voltage by using a reference gamma voltage in response to a plurality of data control signals provided from the timing controller TC. The data drive part DD may supply the converted data voltage to a plurality of data lines DL.

The timing controller TC aligns image data, which are inputted from the outside, and supplies the image data to the data drive part DD. The timing controller TC may generate the gate control signals and the data control signals by using synchronizing signals, for example, dot clock signals, data enable signals, and horizontal/vertical synchronizing signals inputted from the outside. Further, the timing controller TC may control the gate drive part GD and the data drive part DD by supplying the generated gate control signals and data control signals to the gate drive part GD and the data drive part DD.

The display panel PN is configured to display images to a user and includes the plurality of sub-pixels SP. In the display panel PN, the plurality of gate lines GL and the plurality of data lines DL intersect one another, and each of the plurality of sub-pixels SP is connected to the gate line GL and the data line DL. In addition, although not illustrated in the drawings, the plurality of sub-pixels SP may be respectively connected to a high-potential power line, a low-potential power line, a reference line, and the like.

The display panel PN may have a display area AA, and a non-display area NA configured to surround the display area AA.

The display area AA is an area of the display device 100 in which images are displayed. The display area AA may include the plurality of sub-pixels SP constituting the plurality of pixels, and a circuit configured to operate the plurality of sub-pixels SP. The plurality of sub-pixels SP is minimum units that constitute the display area AA. The n sub-pixels SP may constitute a single pixel PX. A light-emitting element 120, a thin-film transistor for operating the light-emitting element 120, and the like may be disposed in each of the plurality of sub-pixels SP. The plurality of light emitting elements 120 may have different configurations depending on the type of display panel PN. For example, in case that the display panel PN is an inorganic light-emitting display panel PN, the light-emitting element 120 may be a light-emitting diode (LED) or a micro light-emitting diode (micro LED).

A plurality of signal lines for transmitting various types of signals to the plurality of sub-pixels SP is disposed in the display area AA. For example, the plurality of signal lines may include the plurality of data lines DL for supplying data voltages to the plurality of sub-pixels SP, and the plurality of gate lines GL for supplying gate voltages to the plurality of sub-pixels SP. The plurality of gate lines GL may extend in one direction in the display area AA and be connected to the plurality of sub-pixels SP. The plurality of data lines DL may extend in a direction different from one direction in the display area AA and be connected to the plurality of sub-pixels SP. In addition, the low-potential power line, the high-potential power line, and the like may be further disposed in the display area AA. However, the present disclosure is not limited thereto.

The non-display area NA may be defined as an area in which no image is displayed, i.e., an area extending from the display area AA. The non-display area NA may include link lines and pad electrodes for transmitting signals to the sub-pixels SP in the display area AA. Alternatively, the non-display area NA may include drive ICs such as gate drivers IC and data drivers IC.

Meanwhile, the non-display area NA may be positioned on a rear surface of the display panel PN, i.e., a surface on which the sub-pixel SP is not present. Alternatively, the non-display area NA may be excluded. However, the present disclosure is not limited to the configuration illustrated in the drawings.

Meanwhile, the drive parts such as the gate drive part GD, the data drive part DD, and the timing controller TC may be connected to the display panel PN in various ways. For example, the gate drive part GD may be mounted in the non-display area NA by a gate-in-panel (GIP) method or mounted between the plurality of sub-pixels SP by a gate-in-active area (GIA) method in the display area AA. For example, the data drive part DD and the timing controller TC may be formed on a separate flexible film and a printed circuit board and electrically connected to the display panel PN by a method of bonding the flexible film and the printed circuit board to a pad electrode formed in the non-display area NA of the display panel PN. In case that the gate drive part GD is mounted by the GIP method and the data drive part DD and the timing controller TC transmit signals to the display panel PN through the pad electrode in the non-display area NA, it is necessary to ensure an area of the non-display area NA in order to dispose the gate drive part GD and the pad electrode, which may increase a bezel.

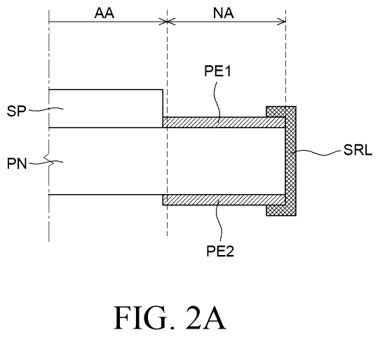

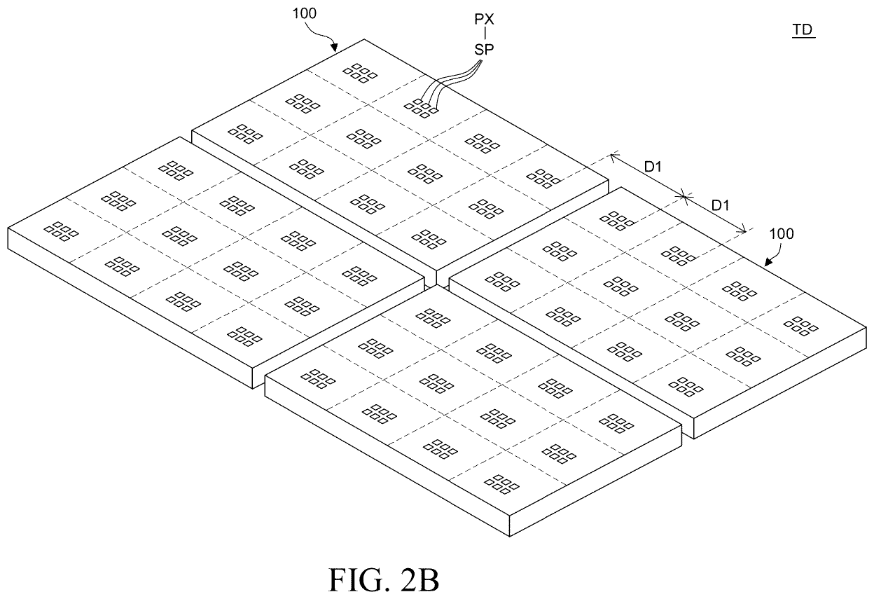

Alternatively, in case that the gate drive part GD is mounted in the display area AA by the GIA method and a side line SRL, which connects a signal line on a front surface of the display panel PN to the pad electrode on the rear surface of the display panel PN, is formed to bond the flexible film and the printed circuit board to the rear surface of the display panel PN, it is possible to minimize the non-display area NA on the front surface of the display panel PN. That is, in case that the gate drive part GD, the data drive part DD, and the timing controller TC are connected to the display panel PN by the above-mentioned method, a zero bezel in which the bezel is not substantially present may be implemented. A more detailed description will be described with reference to FIGS. 2A and 2B.

FIG. 2A is a partial cross-sectional view of the display device according to the exemplary embodiment of the present specification. FIG. 2B is a perspective view of a tiling display device according to the exemplary embodiment of the present specification.

A plurality of pad electrodes for transmitting various types of signals to the plurality of sub-pixels SP is disposed in the non-display area NA of the display panel PN. For example, a first pad electrode PE1 configured to transmit signals to the plurality of sub-pixels SP is disposed in the non-display area NA on the front surface of the display panel PN. A second pad electrode PE2 electrically connected to drive components such as the flexible film and the printed circuit board is disposed in the non-display area NA on the rear surface of the display panel PN.

In this case, although not illustrated in the drawings, various types of signal lines, e.g., the gate line GL, the data line DL, or the like connected to the plurality of sub-pixels SP may extend from the display area AA to the non-display area NA and be electrically connected to the first pad electrode PE1.

Further, the side line SRL is disposed along a side surface of the display panel PN. The side line SRL may electrically connect the first pad electrode PE1 on the front surface of the display panel PN and the second pad electrode PE2 on the rear surface of the display panel PN. Therefore, the signals received from the drive components on the rear surface of the display panel PN may be transmitted to the plurality of sub-pixels SP through the second pad electrode PE2, the side line SRL, and the first pad electrode PE1. Therefore, a signal transmission route is defined from the front surface to the side surface and the rear surface of the display panel PN, which minimizes an area of the non-display area NA of the display panel PN.

Further, with reference to FIG. 2B, a tiling display device TD having a large screen may be implemented by connecting a plurality of display devices 100. In this case, as illustrated in FIG. 2A, in case that the tiling display device TD is implemented by using the display device 100 with the minimized bezel, a seam area in which no image is displayed between the display devices 100 may be minimized, thereby improving display quality.

For example, the plurality of sub-pixels SP may constitute a single pixel PX. An interval D1 between an outermost peripheral pixel PX of one display device 100 and an outermost peripheral pixel PX of another display device 100 adjacent to one display device 100 may be implemented to be equal to the interval D1 between the pixels PX in one display device 100. Therefore, the seam area may be minimized as a constant interval of the pixels PX is implemented between the display device 100 and the display device 100.

However, as illustrated in FIG. 2A and FIG. 2B, the display device 100 according to the exemplary embodiment of the present specification may be a general display device in which the bezel is present. However, the present disclosure is not limited thereto.

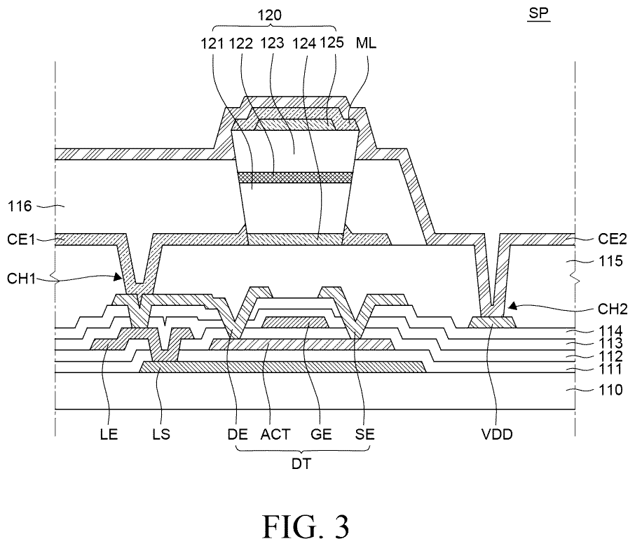

FIG. 3 is a cross-sectional view of the sub-pixel of the display device according to the exemplary embodiment of the present specification. With reference to FIG. 3, the display panel PN of the display device 100 according to the exemplary embodiment of the present specification includes a substrate 110, a buffer layer 111, a gate insulating layer 112, a first interlayer insulating layer 113, a second interlayer insulating layer 114, a bonding layer 115, a first planarization layer 116, a driving transistor DT, the light-emitting element 120, a first connection electrode CE1, a second connection electrode CE2, a light-blocking layer LS, and an auxiliary electrode LE.

With reference to FIG. 3, the substrate 110 is a component for supporting various constituent elements included in the display device 100 and may be made of an insulating material. For example, the substrate 110 may be made of glass, resin, or the like. In addition, the substrate 110 may include plastic such as polymer and may be made of a material having flexibility.

The light-blocking layer LS is disposed on the substrate 110. The light-blocking layer LS blocks light entering an active layer ACT of the driving transistor DT, which will be described below, from a lower side of the substrate 110. The light-blocking layer LS may block light entering the active layer ACT of the driving transistor DT, thereby minimizing a leakage current.

The buffer layer 111 is disposed on the substrate 110 and the light-blocking layer LS. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present disclosure is not limited thereto. However, the buffer layer 111 may be excluded in accordance with the type of substrate 110 or the type of transistor. However, the present disclosure is not limited thereto.

The driving transistor DT is disposed on the buffer layer 111. The driving transistor DT includes the active layer ACT, a gate electrode GE, a source electrode SE, and a drain electrode DE.

The active layer ACT is disposed on the buffer layer 111. The active layer ACT may be made of a semiconductor material such as an oxide semiconductor, amorphous silicon, or polysilicon. However, the present disclosure is not limited thereto.

The gate insulating layer 112 is disposed on the active layer ACT. The gate insulating layer 112 is an insulating layer for insulating the active layer ACT and the gate electrode GE. The gate insulating layer 112 may be configured as a single layer or multilayer made of silicon oxide (SiOx) or silicon nitride (SiNx). However, the present disclosure is not limited thereto.

The gate electrode GE is disposed on the gate insulating layer 112. The gate electrode GE may be electrically connected to the source electrode SE of the driving transistor DT. The gate electrode GE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first interlayer insulating layer 113 and the second interlayer insulating layer 114 are disposed on the gate electrode GE. Contact holes, through which the source electrode SE and the drain electrode DE are connected to the active layer ACT, are formed in the first interlayer insulating layer 113 and the second interlayer insulating layer 114. The first interlayer insulating layer 113 and the second interlayer insulating layer 114 may be insulating layers for protecting a lower portion of the first interlayer insulating layer 113 and a lower portion of the second interlayer insulating layer 114 and each configured as a single layer or multilayer made of silicon oxide (SiOx) or silicon nitride (SiNx). However, the present disclosure is not limited thereto.

The source electrode SE and the drain electrode DE are disposed on the second interlayer insulating layer 114 and electrically connected to the active layer ACT. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Meanwhile, in the present specification, the configuration has been described in which the first interlayer insulating layer 113 and the second interlayer insulating layer 114, i.e., the plurality of insulating layers is disposed between the gate electrode GE, the source electrode SE, and the drain electrode DE. However, only a single insulating layer may be disposed between the gate electrode GE, the source electrode SE, and the drain electrode DE. However, the present disclosure is not limited thereto. However, as illustrated in the drawings, in case that the plurality of insulating layers, such as the first interlayer insulating layer 113 and the second interlayer insulating layer 114, is disposed between the gate electrode GE, the source electrode SE, and the drain electrode DE, an electrode may be additionally formed between the first interlayer insulating layer 113 and the second interlayer insulating layer 114. The additionally formed electrode may define a capacitor together with other components disposed on the lower portion of the first interlayer insulating layer 113 or the upper portion of the second interlayer insulating layer 114.

The auxiliary electrode LE is disposed on the gate insulating layer 112. The auxiliary electrode LE is an electrode that electrically connects the light-blocking layer LS, which is disposed below the buffer layer 111, to any one of the source electrode SE and the drain electrode DE on the second interlayer insulating layer 114. For example, the light-blocking layer LS may be electrically connected to any one of the source electrode SE or the drain electrode DE through the auxiliary electrode LE so as not to be operated as a floating gate, thereby minimizing a change in threshold voltage of the driving transistor DT caused by the floating light-blocking layer LS. The drawing illustrates that the light-blocking layer LS is connected to the drain electrode DE. However, the light-blocking layer LS may be connected to the source electrode SE. However, the present disclosure is not limited thereto.

A power line VDD is disposed on the second interlayer insulating layer 114. The power line VDD may be electrically connected to the light-emitting element 120 together with the driving transistor DT and allow the light-emitting element 120 to emit light. The power line VDD may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The bonding layer 115 is disposed on the driving transistor DT and the power line VDD. The front surface of the substrate 110 may be coated with the bonding layer 115, and the bonding layer 115 may fix the light-emitting element 120 disposed on the bonding layer 115. For example, the bonding layer 115 may be made of any one material selected from adhesive polymer, epoxy resist, UV resin, a polyimide-based material, an acrylate-based material, a urethane-based material, and polydimethylsiloxane (PDMS). However, the present disclosure is not limited thereto.

The light-emitting element 120 is disposed on the bonding layer 115. The light-emitting elements 120 may be elements configured to emit light by using an electric current and include the light-emitting elements 120 configured to emit red light, green light, blue light, and the like. The light-emitting elements 120 may implement light with various colors including white by using a combination of red light, green light, blue light, and the like. For example, the light-emitting element 120 may be a light-emitting diode (LED) or a micro LED. However, the present disclosure is not limited thereto.

The light-emitting element 120 includes a first semiconductor layer 121, a light-emitting layer 122, a second semiconductor layer 123, a first electrode 124, and a second electrode 125. The first semiconductor layer 121, the light-emitting layer 122, the second semiconductor layer 123, and the second electrode 125 may be sequentially disposed on the first electrode 124. Therefore, the light-emitting element 120 is a vertical light-emitting element 120 in which the second electrode 125 is disposed on the first electrode 124.

The first semiconductor layer 121 is disposed on the bonding layer 115, and the second semiconductor layer 123 is disposed on the first semiconductor layer 121. The first semiconductor layer 121 and the second semiconductor layer 123 may each be a layer formed by doping a particular material with n-type and p-type impurities. For example, the first semiconductor layer 121 and the second semiconductor layer 123 may each be a layer formed by doping a material, such as gallium nitride (GaN), indium aluminum phosphide (InAlP), or gallium arsenic (GaAs) with p-type or n-type impurities. Further, the p-type impurity may be magnesium, zinc (Zn), beryllium (Be), or the like. The n-type impurity may be silicon (Si), germanium, tin (Sn), or the like. However, the present disclosure is not limited thereto.

The light-emitting layer 122 is disposed between the first semiconductor layer 121 and the second semiconductor layer 123. The light-emitting layer 122 may emit light by receiving positive holes and electrons from the first semiconductor layer 121 and the second semiconductor layer 123. The light-emitting layer 122 may be configured as a single layer or a multi-quantum well (MQW) structure. For example, the light-emitting layer 122 may be made of indium gallium nitride (InGaN), gallium nitride (GaN), or the like. However, the present disclosure is not limited thereto.

The first electrode 124 is disposed below the first semiconductor layer 121. The first electrode 124 may be disposed on a bottom surface of the first semiconductor layer 121. The first electrode 124 is an electrode that electrically connects the driving transistor DT and the first semiconductor layer 121. The first electrode 124 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second electrode 125 is disposed on the second semiconductor layer 123. The second electrode 125 is an electrode that electrically connects the second semiconductor layer 123 and the power line VDD. The second electrode 125 may be made of an electrically conductive material, e.g., a transparent conductive material such as indium tin oxide (ITO) or indium zinc oxide (IZO). However, the present disclosure is not limited thereto.

Meanwhile, the light-emitting element 120 has an inversely tapered shape. The light-emitting element 120 may have an inversely tapered shape having a width that increases from below to above. The first semiconductor layer 121 may have a top surface larger in area than a bottom surface. The second semiconductor layer 123 may also have a top surface larger in area than a bottom surface. The light-emitting element 120 may have an inversely tapered shape, such that the first connection electrode CE1 may be self-aligned to be connected only to the first semiconductor layer 121 and the first electrode 124. A more detailed description thereof will be described below.

Further, although not illustrated in the drawings, the light-emitting element 120 may further include a sealing layer that surrounds the light-emitting element 120. The sealing layer may at least surround the first semiconductor layer 121, the light-emitting layer 122, and the second semiconductor layer 123 of the light-emitting element 120. The sealing layer may be made of an insulating material and protect the first semiconductor layer 121, the light-emitting layer 122, and the second semiconductor layer 123. Further, a contact hole, through which the first electrode 124 and the second electrode 125 are exposed, may be formed in the sealing layer, such that the first connection electrode CE1, the second connection electrode CE2, the first electrode 124, and the second electrode 125, which are formed subsequently, may be electrically connected.

Meanwhile, in the present specification, the configuration has been described in which the light-emitting element 120 includes the first semiconductor layer 121, the light-emitting layer 122, the second semiconductor layer 123, the first electrode 124, and the second electrode 125. The light-emitting element 120 may exclude the first electrode 124 or the like in accordance with design. However, the present disclosure is not limited thereto.

Next, the first connection electrode CE1 is disposed on the bonding layer 115. The first connection electrode CE1 is an electrode that electrically connects the light-emitting element 120 and the driving transistor DT. The first connection electrode CE1 may be electrically connected to any one of the source electrode SE and the drain electrode DE of the driving transistor DT through a first contact hole CH1 formed in the bonding layer 115. Further, the first connection electrode CE1 may be disposed to surround a lower side surface of the light-emitting element 120, i.e., a side surface of the first semiconductor layer 121 and a side surface of the first electrode 124 and electrically connected to the first semiconductor layer 121 and the first electrode 124. Therefore, the first connection electrode CE1 may electrically connect the drain electrode DE of the driving transistor DT and the first electrode 124 and the first semiconductor layer 121 of the light-emitting element 120.

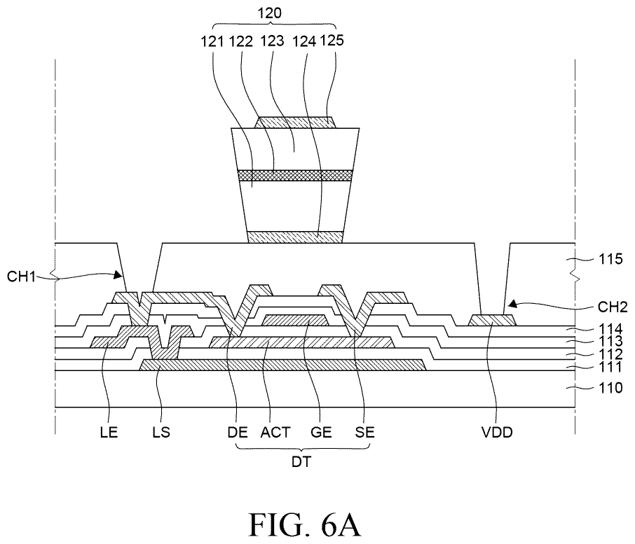

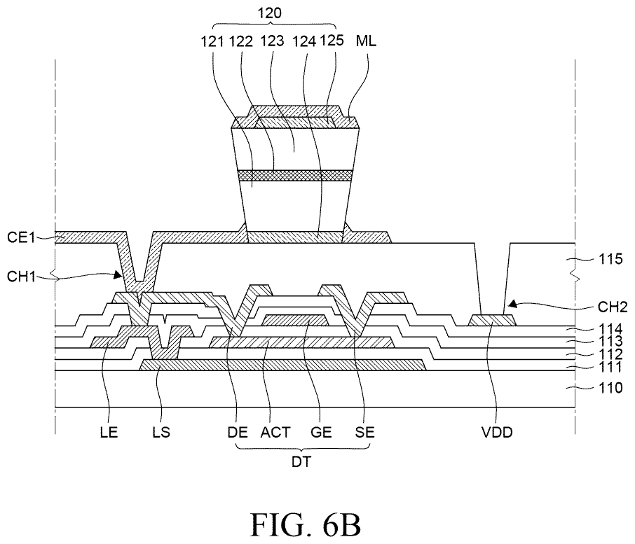

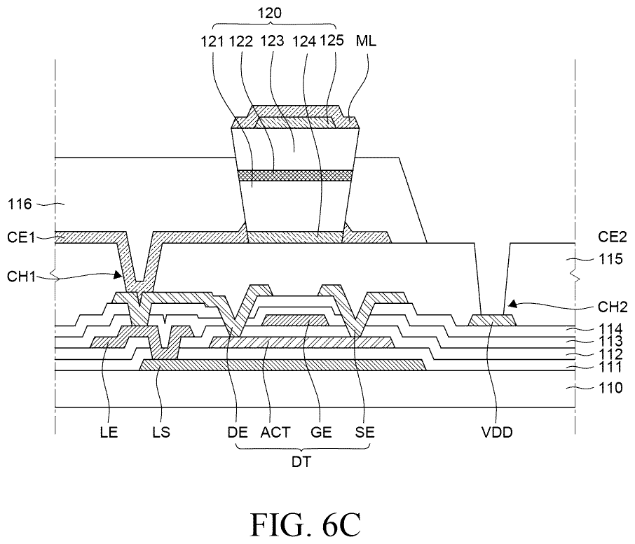

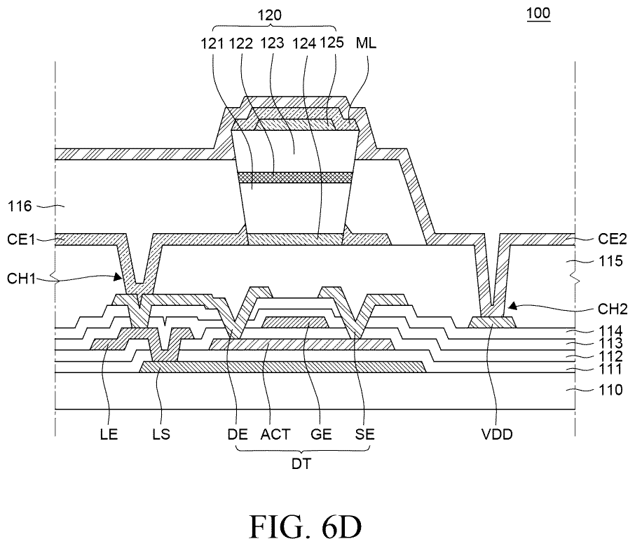

Meanwhile, a metal layer ML is disposed on the light-emitting element 120. The metal layer ML may be formed on an upper portion of the light-emitting element 120 during a process of forming the first connection electrode CE1. In case that a metallic material is formed on the light-emitting element 120, the metallic material cannot be deposited to the side surface of the light-emitting element 120 having an inversely tapered shape, such that the first connection electrode CE1 and the metal layer ML may be formed and separated. Therefore, during the process of forming the first connection electrode CE1, the metal layer ML may be formed at an upper side of the light-emitting element 120, and the metal layer ML may be disposed in a state of being disconnected from the first connection electrode CE1 by the light-emitting element 120 having an inversely tapered shape. A more detailed description thereof will be described below with reference to FIG. 6B.

The first planarization layer 116 is disposed on the first connection electrode CE1 and the light-emitting element 120. The first planarization layer 116 may planarize an upper portion of the substrate 110 on which the light-emitting element 120 is disposed. The first planarization layer 116, together with the bonding layer 115, may fix the light-emitting element 120 onto the substrate 110. The first planarization layer 116 may be configured as a single layer or multilayer and made of a photoresist or an acrylic-based organic material, for example. However, the present disclosure is not limited thereto.

The first planarization layer 116 may be partially formed in an area of the substrate 110 that at least overlaps the light-emitting element 120 and the first connection electrode CE1. The first planarization layer 116 is opened in an area that overlaps the power line VDD so that a second contact hole CH2 of the bonding layer 115 is exposed to the outside.

Meanwhile, the first planarization layer 116 may be formed to at least cover the first semiconductor layer 121 and the light-emitting layer 122 of the light-emitting element 120. A thickness of the first planarization layer 116 may be larger than a sum of a thickness of the first semiconductor layer 121 of the light-emitting element 120 and a thickness of the light-emitting layer 122. Further, the thickness of the first planarization layer 116 may be smaller than an overall thickness of the light-emitting element 120. For example, a top surface of the first planarization layer 116 may be disposed to be at a height at least higher than a height of the light-emitting layer 122 of the light-emitting element 120. The top surface of the first planarization layer 116 may be disposed to be at a height equal to or lower than a height of the top surface of the second semiconductor layer 123. During the process of manufacturing the display device 100, the self-alignment may be performed so that only the second semiconductor layer 123 and the second electrode 125 are exposed from the first planarization layer 116, and the second connection electrode CE2 may be electrically connected only to the second semiconductor layer 123 and the second electrode 125. A more detailed description thereof will be described below with reference to FIGS. 6C and 6D.

The second connection electrode CE2 is disposed on the first planarization layer 116. The second connection electrode CE2 is an electrode that electrically connects the light-emitting element 120 and the power line VDD. The second connection electrode CE2 may be electrically connected to the power line VDD through the second contact hole CH2 formed in an area of the bonding layer 115 exposed from the first planarization layer 116. Further, the second connection electrode CE2 may be disposed to cover the upper portion of the light-emitting element 120 exposed from the first planarization layer 116 and electrically connected to the second electrode 125 and the second semiconductor layer 123. For example, the second connection electrode CE2 may be disposed to cover a side surface of the second semiconductor layer 123 and a top surface of the metal layer ML and electrically connected to the second semiconductor layer 123 and the second electrode 125.

Meanwhile, the light-emitting element 120, the first connection electrode CE1, and the second connection electrode CE2 of the display device 100 according to the exemplary embodiment of the present specification may be formed in a self-alignment manner. That is, it is possible to easily form the first connection electrode CE1 and the second connection electrode CE2, which are connected to the first electrode 124 and the second electrode 125 of the light-emitting element 120, in a self-alignment manner without a separate alignment process. In addition, the first connection electrode CE1 and the second connection electrode CE2 are formed in a self-alignment manner, which may minimize a short-circuit defect caused by an alignment position error and ensure a transfer margin.

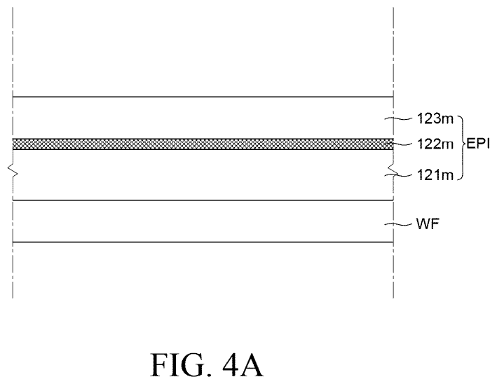

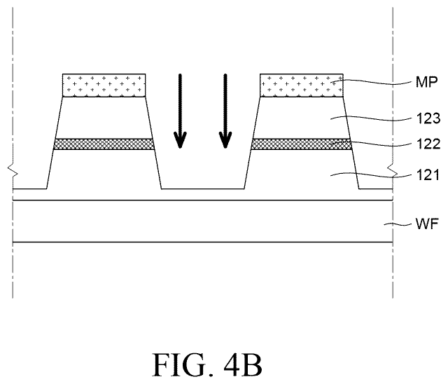

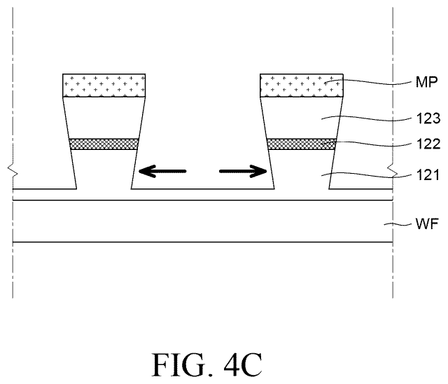

Hereinafter, a method of manufacturing the display device 100 according to the exemplary embodiment of the present specification will be described with reference to FIGS. 4A to 6D.

FIGS. 4A to 4C are process diagrams for explaining a method of manufacturing the light-emitting element 120 of the display device according to the exemplary embodiment of the present specification.

With reference to FIG. 4A, an epilayer EPI is grown on a wafer WF. The epilayer EPI may be a layer formed by growing materials that constitutes the first semiconductor layer 121, the light-emitting layer 122, and the second semiconductor layer 123 of the light-emitting element 120. The plurality of light-emitting elements 120 may be formed by patterning the plurality of epilayers EPI. For example, a first semiconductor material layer 121m, which constitutes the first semiconductor layer 121, a light-emitting material layer 122m, which constitutes the light-emitting layer 122, and a second semiconductor material layer 123m, which constitutes the second semiconductor layer 123, may be sequentially grown on the wafer WF.

Next, with reference to FIG. 4B, a mask pattern MF is formed on the epilayer EPI, and the epilayer EPI is etched. The plurality of epilayers EPI may be patterned through an etching process. In this case, dry etching may be performed by using the mask pattern MF. In the dry etching, a horizontal etching speed and a vertical etching speed may be different from each other. In general, the vertical etching speed may be higher than the horizontal etching speed. Therefore, the dry etching may etch a portion, which does not overlap the mask pattern MF, in a depth direction while minimizing undercut made when a portion overlapping the mask pattern MF is etched. The dry etching may divide the epilayer EPI into the plurality of first semiconductor layers 121, the light-emitting layer 122, and the second semiconductor layer 123.

Next, with reference to FIG. 4C, the light-emitting element 120 having an inversely tapered shape is formed by performing an additional etching process on the plurality of first semiconductor layers 121, the plurality of light-emitting layers 122, and the plurality of second semiconductor layers 123. In this case, the light-emitting element 120 having an inversely tapered shape may be performed by performing wet etching using tetramethyl ammonium hydroxide (TMAH). The TMAH is characterized in that a horizontal etching speed is higher than a vertical etching speed when the epilayer EPI is etched. Therefore, in the wet etching process using the TMAH, the etching may be more quickly performed in a direction of a side surface of the epilayer EPI than a depth direction of the epilayer EPI. The etching may be performed in a direction in which the widths of the plurality of first semiconductor layers 121, the plurality of light-emitting layers 122, and the plurality of second semiconductor layers 123 decrease. Therefore, the light-emitting element 120 having an inversely tapered shape may be formed by performing the wet etching using the TMAH.

Further, when the light-emitting element 120 having an inversely tapered shape is completely formed, the mask pattern MF may be removed, and the first electrode 124 and the second electrode 125 are formed, such that the light-emitting element 120 may be completely formed.

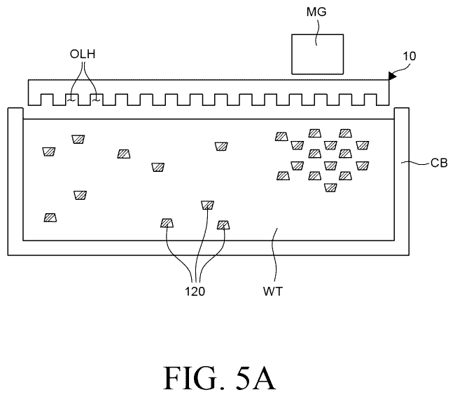

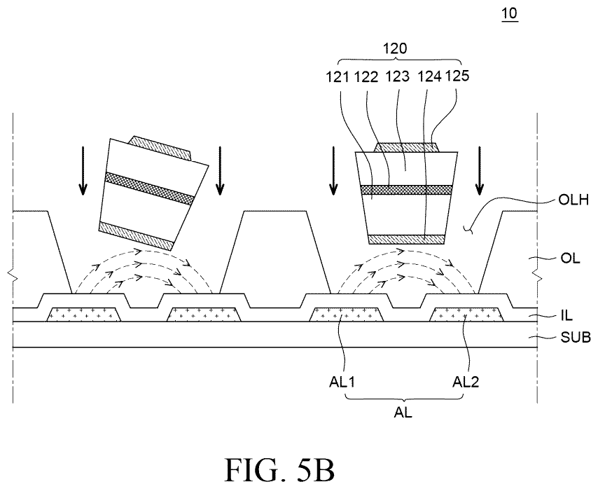

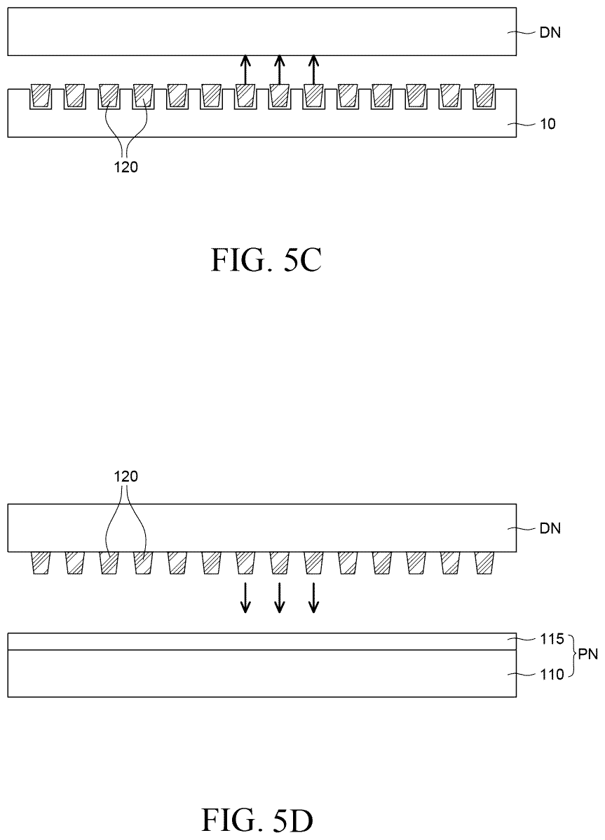

FIGS. 5A to 5D are process diagrams for explaining a self-assembling method of assembling the light-emitting element 120 of the display device according to the exemplary embodiment of the present specification.

Next, with reference to FIG. 5A to 5D, the light-emitting element 120 may be transferred to the substrate 110 by the self-assembling method.

First, with reference to FIG. 5A, the light-emitting element 120 is inputted to a chamber CB filled with a fluid WT. The fluid WT may include water or the like, and the chamber CB filled with the fluid WT may have a shape opened at an upper side thereof.

Next, an assembling substrate 10 may be positioned on the chamber CB filled with the light-emitting element 120. The assembling substrate 10 is the substrate 110 on which the light-emitting element 120 is temporarily self-assembled. After the light-emitting element 120 is self-assembled on the assembling substrate 10, the light-emitting element 120 on the assembling substrate 10 may be transferred to the display device 100.

Next, a magnet MG may be positioned on the assembling substrate 10. The light-emitting elements 120, which are submerged or suspended on a bottom of the chamber CB, may be moved toward the assembling substrate 10 by a magnetic force of the magnet MG.

In this case, the light-emitting element 120 may include a magnetic element so that the light-emitting element 120 may be moved by a magnetic field. For example, any one of the first electrode 124 and the second electrode 125 of the light-emitting element 120 may include ferromagnetic materials such as iron or cobalt, such that a direction of the light-emitting element 120 directed toward the magnet MG may be aligned.

Next, the light-emitting element 120, which has been moved toward the assembling substrate 10 by the magnet MG, may be self-assembled to the assembling substrate 10 by an electric field formed by a plurality of assembling lines AL.

Specifically, with reference to FIG. 5B, the assembling substrate 10 includes an assembly substrate SUB, the plurality of assembling lines AL, an assembling insulating layer IL, and an organic layer OL.

First, the plurality of assembling lines AL is disposed on the assembly substrate SUB. The plurality of assembling lines AL includes a plurality of first assembling lines AL1 and a plurality of second assembling lines AL2. The plurality of first assembling lines AL1 and the plurality of second assembling lines AL2 may be disposed to be spaced apart from one another at predetermined intervals.

The assembling insulating layer IL is disposed on the plurality of assembling lines AL. The assembling insulating layer IL may protect the plurality of assembling lines AL from the fluid WT, thereby suppressing a defect such as corrosion of the plurality of assembling lines AL.

The organic layer OL including a plurality of pockets OLH is disposed on the assembling insulating layer IL. Each of the plurality of pockets OLH, which is formed by opening a part of the organic layer OL, may be an area in which the plurality of light-emitting elements 120 is self-assembled. The plurality of pockets OLH may be disposed so as to overlap an area between a pair of first and second assembling lines AL1 and AL2. Thereafter, the plurality of pockets OLH may each be formed at positions respectively corresponding to the plurality of sub-pixels SP of the display device 100. The plurality of pockets OLH may be disposed to respectively correspond to the plurality of sub-pixels SP in a one-to-one manner. The light-emitting elements 120 self-assembled in the plurality of pockets OLH may be transferred to the plurality of sub-pixels SP without change.

Further, the plurality of light-emitting elements 120 may be self-assembled in the pockets OLH of the organic layer OL by applying voltages to the plurality of assembling lines AL. For example, an electric field may be formed by applying alternating current voltages to the plurality of first assembling lines AL1 and the plurality of second assembling lines AL2. The light-emitting element 120 may have a polarity by being dielectrically polarized by the electric field. Further, the dielectrically polarized light-emitting element 120 may be fixed or moved in a particular direction by dielectrophoresis (DEP), i.e., the electric field. Therefore, the plurality of light-emitting elements 120 may be temporarily self-assembled inside the pockets OLH of the assembling substrate 10 by using the dielectrophoresis.

In this case, the light-emitting element 120 may be self-assembled in the pocket OLH so that the first semiconductor layer 121 further extends downward than the second semiconductor layer 123. That is, the light-emitting element 120 may be self-assembled in an inversely tapered shape in the pocket OLH.

However, the light-emitting element 120 may be self-assembled in the pocket OLH so as to have a tapered shape in which the second semiconductor layer 123 is disposed below the first semiconductor layer 121. However, the present disclosure is not limited thereto.

Next, with reference to FIG. 5C, the plurality of light-emitting elements 120 of the assembling substrate 10 is transferred to a donor DN.

First, the assembling substrate 10 and the donor DN are aligned so that the plurality of light-emitting elements 120 and the donor DN face one another. Further, the assembling substrate 10 and the donor DN may be joined, such that an upper portion of the light-emitting element 120 may be in contact with the donor DN. In this case, the donor DN is made of a material having an adhesive force, such that the upper portions of the plurality of light-emitting elements 120 may be bonded to the donor DN and transferred to the donor DN from the assembling substrate 10. The donor DN may be made of a polymer material having viscoelasticity, e.g., polydimethylsiloxane (PDMS), polyurethane acrylate (PUA), polyethylene glycol (PEG), polymethylmethacrylate (PMMA), polystyrene (PS), epoxy resin, urethane resin, acrylic resin, or the like. However, the present disclosure is not limited thereto.

Next, with reference to FIG. 5D, the plurality of light-emitting elements 120 on the donor DN is transferred onto the bonding layer 115 of the display device 100.

The donor DN and the display device 100 formed with the bonding layer 115 are aligned. The display device 100 and the donor DN may be aligned so that the plurality of light-emitting elements 120 of the donor DN and the bonding layer 115 of the display device 100 face one another. Further, the donor DN and the display device 100 may be joined, such that the light-emitting element 120 on the donor DN may be transferred onto the bonding layer 115.

In this case, a bonding force between the bonding layer 115 and the light-emitting element 120 is higher than a bonding force between the donor DN and the light-emitting element 120, such that the light-emitting element 120 may be detached from the donor DN and attached to the bonding layer 115.

Therefore, the light-emitting elements 120 each having an inversely tapered shape may be formed on the wafer WF, the light-emitting elements 120 may be self-assembled so as to be arranged on the assembling substrate 10 while corresponding to the plurality of sub-pixels SP, and then the plurality of light-emitting elements 120 on the assembling substrate 10 may be transferred to the display device 100 by using the donor DN. In this case, it is possible to omit the process of transferring the plurality of light-emitting elements 120 to the donor DN from the wafer WF after aligning the plurality of light-emitting elements 120 so that the plurality of light-emitting elements 120 corresponds to the intervals between the plurality of sub-pixels SP. The light-emitting element 120 may be easily self-assembled at an exact position by using an electric field. Therefore, the plurality of light-emitting elements 120 on the wafer WF is self-assembled by using the assembling substrate 10, which may minimize an alignment error and simplify the process of transferring the plurality of light-emitting elements 120.

In the present specification, the configuration has been described in which the plurality of light-emitting elements 120 is self-assembled to the assembling substrate 10 by the self-assembling method and then transferred to the display device 100 by using the donor DN. However, the present disclosure is not limited thereto. For example, the plurality of light-emitting elements 120 may be transferred directly to the donor DN from the wafer WF and transferred to the display device 100 without the self-assembling method. The plurality of light-emitting elements 120 may be self-assembled directly to the display device 100 by forming a separate assembling line AL in the display device 100. However, the present disclosure is not limited thereto.

FIGS. 6A to 6D are process diagrams for explaining a process of forming the first connection electrode CE1 and the second connection electrode CE2 of the display device according to the exemplary embodiment of the present specification.

With reference to FIGS. 6A to 6D, the light-emitting element 120 is transferred onto the bonding layer 115 of the display device 100, and then the first connection electrode CE1 and the second connection electrode CE2 are formed, such that the light-emitting element 120 may be electrically connected to the driving transistor DT and the power line VDD.

First, with reference to FIG. 6A, the first contact hole CH1 and the second contact hole CH2 are formed in the bonding layer 115 through a mask process. The first contact hole CH1, which exposes the drain electrode DE, and the second contact hole CH2, which overlaps the power line VDD, may be formed in the bonding layer 115.

Further, the light-emitting element 120 may be transferred onto the bonding layer 115, which has the first contact hole CH1 and the second contact hole CH2, through the transfer process described with reference to FIGS. 5A to 5D.

Next, with reference to FIG. 6B, a metallic material layer, which covers the light-emitting element 120, is formed. The metallic material layer may be formed to cover the light-emitting element 120 and an area adjacent to the light-emitting element 120. For example, the metallic material layer may be formed to cover the upper portion of the light-emitting element 120 and a top surface of the bonding layer 115 adjacent to the light-emitting element 120. Further, the metallic material layer may be formed to cover the area in which the first contact hole CH1 is formed. Therefore, a part of the metallic material layer, which is disposed on the bonding layer 115 and connects the first contact hole CH1 and a lower portion of the light-emitting element 120, may be the first connection electrode CE1.

In this case, the metallic material layer may be made of a metallic material having low step coverage and disconnected at a position in the vicinity of an upper edge of the light-emitting element 120 without covering the entire side surface of the light-emitting element 120 having an inversely tapered shape. Further, the metal layer ML of the metallic material layer, which covers the upper portion of the light-emitting element 120, is disconnected from the first connection electrode CE1 disposed on the top surface of the bonding layer 115 by the light-emitting element 120 having an inversely tapered shape and only serves as an electrode layer that merely covers the upper portion of the light-emitting element 120.

For example, the metallic material layer may be deposited by a physical vapor deposition (PVD) method. In case that the physical vapor deposition method is used, the metallic material may be deposited on the substrate 110 while moving rectilinearly from a target material. However, the metallic material, which is to move toward the side surface of the light-emitting element 120, is covered by the upper portion of the light-emitting element 120, such that the metallic material cannot move toward the side surface of the light-emitting element 120, and the deposition on the side surface of the light-emitting element 120 may be hindered. Therefore, the metallic material cannot be normally deposited on the side surface of the light-emitting element 120 having an inversely tapered shape, and the metallic materials formed around the upper and lower portions of the light-emitting element 120 may be disconnected from each other and divided into the first connection electrode CE1 and the metal layer ML.

Therefore, the metallic material layer is formed to cover the light-emitting element 120 and a part of the bonding layer 115 having the first contact hole CH1, such that the first connection electrode CE1, which electrically connects the first semiconductor layer 121 of the light-emitting element 120 and the driving transistor DT, may be formed in a self-alignment manner. Further, the metal layer ML, which covers the upper portion of the light-emitting element 120, is formed together with the first connection electrode CE1, but the metal layer ML is disconnected from the first connection electrode CE1 by the light-emitting element 120 having an inversely tapered shape. Therefore, it is possible to suppress a short-circuit defect of the first semiconductor layer 121 and the second semiconductor layer 123.

Next, with reference to FIG. 6C, the first planarization layer 116 is formed to cover the light-emitting element 120 and the first connection electrode CE1. The first planarization layer 116 may be disposed in an area that overlaps the light-emitting element 120 and the first connection electrode CE1. The first planarization layer 116 may be disposed to cover the first semiconductor layer 121 and the light-emitting layer 122 of the light-emitting element 120. The second contact hole CH2, through which the power line VDD is exposed, may be exposed from the first planarization layer 116, and the second semiconductor layer 123 and the second electrode 125 of the light-emitting element 120 may be exposed from the first planarization layer 116. The first planarization layer 116 may be disposed to cover the first connection electrode CE1, the first semiconductor layer 121, and the light-emitting layer 122, thereby suppressing a short-circuit defect of the second connection electrode CE2.

Meanwhile, an ashing process may be performed to adjust a thickness of the first planarization layer 116. For example, the ashing process, which decreases an overall thickness of a first planarization material layer is performed after the first planarization material layer is formed on the front surface of the substrate 110, such that a thickness of the first planarization layer 116 may be set to a thickness between an overall thickness of the light-emitting element 120 and a sum of a thickness of the first semiconductor layer 121 and a thickness of the light-emitting layer 122. However, the present disclosure is not limited thereto.

With reference to FIG. 6D, the second connection electrode CE2 is formed on the first planarization layer 116 and the light-emitting element 120. The second connection electrode CE2, which electrically connects the power line VDD and the upper portion of the light-emitting element 120 exposed from the first planarization layer 116, may be formed by forming an electrically conductive material layer on the front surface of the substrate 110. The second connection electrode CE2 may be electrically connected to the second electrode 125 and the second semiconductor layer 123 while adjoining the metal layer ML and electrically connected to the power line VDD through the second contact hole CH2.

In this case, because only the power line VDD of the second contact hole CH2 and the upper portion of the light-emitting element 120 are exposed from the first planarization layer 116, the second connection electrode CE2 may be formed in a self-alignment manner without a separate alignment process. Even though the electrically conductive material layer, which constitutes the second connection electrode CE2, is formed on the front surface of the substrate 110, the second connection electrode CE2 may be electrically connected only to the second semiconductor layer 123 and the power line VDD by the first planarization layer 116. Therefore, because the first planarization layer 116 is disposed to cover the first connection electrode CE1 and the first semiconductor layer 121, it is possible to suppress a short-circuit defect even though the second connection electrode CE2 is formed on the front surface of the substrate 110.

Meanwhile, in the present specification, the configuration has been described in which the second connection electrode CE2 is formed in the state in which the metal layer ML is present to cover the upper side of the light-emitting element 120. However, the metal layer ML may be removed during an intermediate process, such that the second connection electrode CE2 may directly adjoin the second electrode 125.

Therefore, in the display device 100 and the method of manufacturing the display device 100 according to the exemplary embodiment of the present specification, the first connection electrode CE1 may be formed in a self-alignment manner and electrically connected to the first semiconductor layer 121 of the light-emitting element 120. Specifically, first, a metallic material layer may be formed to cover the light-emitting element 120. In this case, because the light-emitting element 120 has an inversely tapered shape, the metallic material layer may be disconnected without being formed to cover the entire side surface of the light-emitting element 120 having an inversely tapered shape. Therefore, the metal layer ML formed on the upper portion of the light-emitting element 120 may be disconnected from the first connection electrode CE1 that surrounds the lower portion of the light-emitting element 120. The first connection electrode CE1 may electrically connect only the driving transistor DT and the first semiconductor layer 121. Therefore, at the time of forming the metallic material layer on the substrate 110, the first connection electrode CE1 may be formed without a separate alignment process, such that the process of forming the first connection electrode CE1 may be simplified.

In addition, in the display device 100 and the method of manufacturing the display device 100 according to the exemplary embodiment of the present specification, the second connection electrode CE2 may be formed in a self-alignment manner and electrically connected to the second semiconductor layer 123 of the light-emitting element 120. After the first connection electrode CE1 is formed, the first planarization layer 116 may be formed to cover the first connection electrode CE1 and the first semiconductor layer 121 and the light-emitting layer 122 of the light-emitting element 120. In this case, even though the second connection electrode CE2 is formed on the front surface of the substrate 110, the second connection electrode CE2 may be separated from the first connection electrode CE1 and the first semiconductor layer 121 by the first planarization layer 116. Therefore, it is possible to suppress a short-circuit defect of the second connection electrode CE2. Therefore, the second connection electrode CE2 may be formed in a self-alignment manner by forming the electrically conductive material layer on the front surface of the substrate 110 without precisely aligning a position at which the first connection electrode CE1 is formed and a position at which the light-emitting element 120 is formed. Therefore, it is possible to simplify the process of manufacturing the display device 100.

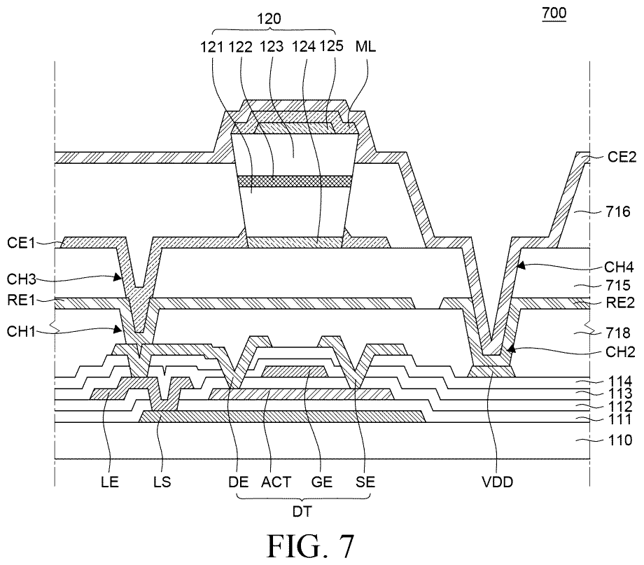

FIG. 7 is a cross-sectional view of a display device according to another exemplary embodiment of the present specification. A display device 700 in FIG. 7 is substantially identical in configuration to the display device 100 in FIGS. 1 to 3, except that the display device 700 further includes a passivation layer 718, a first reflective electrode RE1, and a second reflective electrode RE2. Therefore, repeated descriptions of the identical components will be omitted.

With reference to FIG. 7, the passivation layer 718 is disposed on the driving transistor DT and the power line VDD. The passivation layer 718 may be configured as a single layer or multilayer made of an inorganic material, e.g., a photoresist, an acrylic-based organic material, silicon oxide (SiOx), or silicon nitride (SiNx). However, the present disclosure is not limited thereto.

The first reflective electrode RE1 and the second reflective electrode RE2, which are spaced apart from each other, are disposed between the passivation layer 718 and a bonding layer 715. The first reflective electrode RE1 is a reflective plate that reflects light, which is emitted from the light-emitting element 120, to the upper portion of the light-emitting element 120 while electrically connecting the driving transistor DT and the first connection electrode CE1. The second reflective electrode RE2 is a reflective plate that reflects light, which is emitted from the light-emitting element 120, to the upper portion of the light-emitting element 120 while electrically connecting the power line VDD and the second connection electrode CE2. The first reflective electrode RE1 and the second reflective electrode RE2 may each be made of an electrically conductive material having excellent reflection performance and reflect the light, which is emitted from the light-emitting element 120, toward the upper portion of the light-emitting element 120.

The first reflective electrode RE1 may be electrically connected to the drain electrode DE of the driving transistor DT through the first contact hole CH1 of the passivation layer 718. The second reflective electrode RE2 may be electrically connected to the power line VDD through the second contact hole CH2 of the passivation layer 718.

Further, the first reflective electrode RE1 and the first connection electrode CE1 may be electrically connected to each other through a third contact hole CH3 of the bonding layer 715. The second reflective electrode RE2 and the second connection electrode CE2 may be electrically connected to each other through a fourth contact hole CH4 of the bonding layer 715.

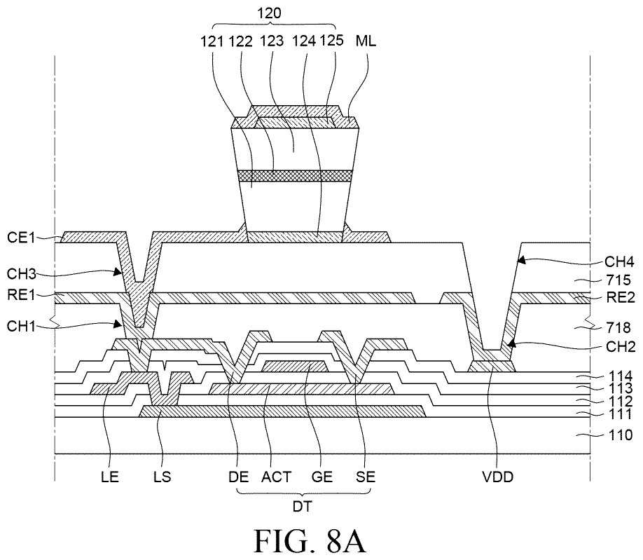

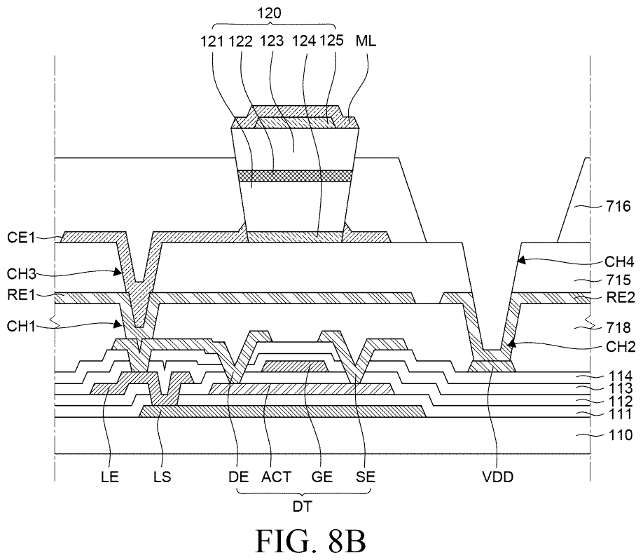

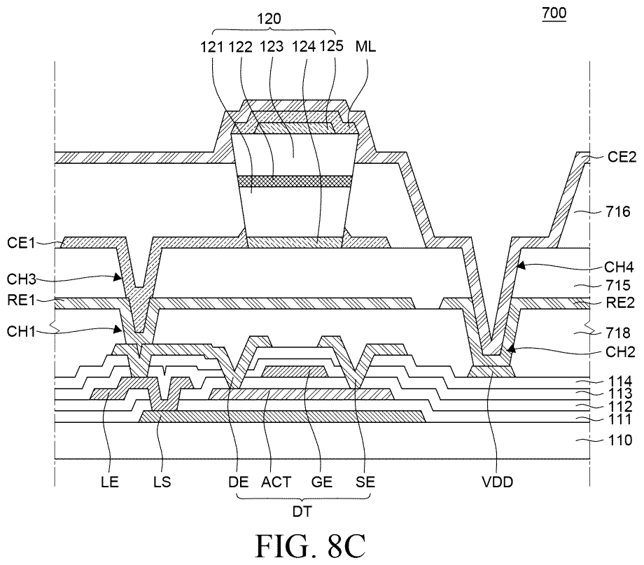

Hereinafter, a method of manufacturing the display device 700 according to another exemplary embodiment of the present specification will be described with reference to FIGS. 8A to 8C.

FIGS. 8A to 8C are process diagrams for explaining a method of manufacturing the display device according to another exemplary embodiment of the present specification.

With reference to FIG. 8A, the first reflective electrode RE1 and the second reflective electrode RE2 are formed on the passivation layer 718, and the bonding layer 715 is formed on the first reflective electrode RE1 and the second reflective electrode RE2. Further, the third contact hole CH3 and the fourth contact hole CH4 are formed in the bonding layer 715. The first reflective electrode RE1 connected to the drain electrode DE of the driving transistor DT may be exposed through the third contact hole CH3. Further, the second reflective electrode RE2 connected to the power line VDD may be exposed through the fourth contact hole CH4.

Next, the light-emitting element 120 is transferred onto the bonding layer 715, and the metallic material layer is formed on the light-emitting element 120 and the bonding layer 715. The metallic material layer may be patterned in the area that overlaps the second reflective electrode RE2, and the metallic material may be formed to overlap the light-emitting element 120 and the first contact hole CH1. The metallic material layer may overlap the light-emitting element 120 and the first reflective electrode RE1 without overlapping the second reflective electrode RE2. In this case, the metallic material layer may be disposed on the top surface of the bonding layer 715 and the metal layer ML present on the upper portion of the light-emitting element 120 by the light-emitting element 120 having an inversely tapered shape. The metallic material layer may be separated and formed as the first connection electrode CE1 that surrounds the lower portion of the light-emitting element 120. Therefore, the first connection electrode CE1, which is disposed on the bonding layer 715 and surrounds the lower portion of the light-emitting element 120, may be electrically connected to the first reflective electrode RE1 through the third contact hole CH3.

With reference to FIG. 8B, a first planarization layer 716 is formed on the light-emitting element 120 and the first connection electrode CE1. In this case, a part of the first planarization layer 716, which overlaps the fourth contact hole CH4, may be removed to electrically connect the second connection electrode CE2 and the second reflective electrode RE2 formed subsequently.

The first planarization layer 716 may be formed to cover only the first semiconductor layer 121 and the light-emitting layer 122 of the light-emitting element 120 without covering the second semiconductor layer 123 and the second electrode 125 of the light-emitting element 120. In this case, a thickness of the first planarization layer 716 may be adjusted by an ashing process or the like so that a top surface of the first planarization layer 716 is positioned on the light-emitting layer 122.

Next, with reference to FIG. 8C, the second connection electrode CE2 is formed on the first planarization layer 716. The second connection electrode CE2 may cover the metal layer ML and the upper portion of the light-emitting element 120 exposed from the first planarization layer 716 and be connected to the second reflective electrode RE2 exposed through the fourth contact hole CH4. Therefore, the second connection electrode CE2 may be electrically connected to the second semiconductor layer 123 and the second electrode 125 of the light-emitting element 120 while adjoining the metal layer ML and electrically connect the power line VDD to the light-emitting element 120 through the fourth contact hole CH4.

In the display device 700 and the method of manufacturing the display device 700 according to still another exemplary embodiment of the present specification, the first reflective electrode RE1 and the second reflective electrode RE2 may be formed, thereby improving luminous efficiency of the display device 700. The first reflective electrode RE1 and the second reflective electrode RE2, which are each made of an electrically conductive material having excellent reflection performance, may be disposed below the light-emitting element 120. The first reflective electrode RE1 and the second reflective electrode RE2 may reflect the light beams, which propagate toward the lower portion of the substrate 110 among the light beams emitted from the light-emitting element 120, to the upper portion of the substrate 110 again, thereby improving luminous efficiency of the display device 700. In this case, the first reflective electrode RE1 and the second reflective electrode RE2 may each be used as an electrode for operating the light-emitting element 120 without merely serving as the reflective plate that reflects light. For example, the first reflective electrode RE1 may be disposed between the passivation layer 718 and the bonding layer 715 and electrically connect the first connection electrode CE1 and the drain electrode DE of the driving transistor DT. The second reflective electrode RE2 may be disposed between the passivation layer 718 and the bonding layer 715 and electrically connect the second connection electrode CE2 and the power line VDD. Therefore, in the display device 700 according to still another exemplary embodiment of the present specification, the first reflective electrode RE1 and the second reflective electrode RE2 may be used to improve luminous efficiency of the display device 700 and connect the light-emitting element 120 to the driving transistor DT and the power line VDD to operate the light-emitting element 120.

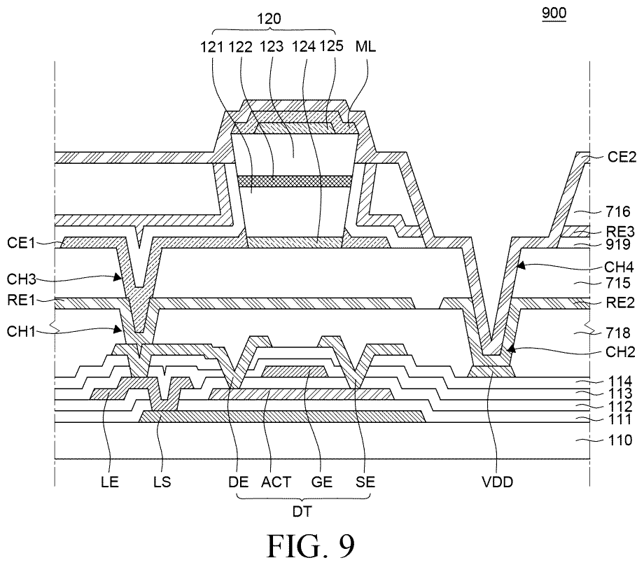

FIG. 9 is a cross-sectional view of a display device according to still another exemplary embodiment of the present specification. A display device 900 in FIG. 9 is substantially identical in configuration to the display device 700 in FIG. 7, except that the display device 900 further includes a third interlayer insulating layer 919 and a third reflective electrode RE3. Therefore, repeated descriptions of the identical components will be omitted.

With reference to FIG. 9, the third interlayer insulating layer 919 is disposed to cover the bonding layer 715 and the first connection electrode CE1 and surrounds the side surface of the light-emitting element 120. The third interlayer insulating layer 919 is a layer that insulates the third reflective electrode RE3, the first connection electrode CE1, and the first semiconductor layer 121 and the first electrode 124 of the light-emitting element 120. The third interlayer insulating layer 919 may be formed on the front surface of the substrate 110 on which the first connection electrode CE1 and the light-emitting element 120 are formed. The third interlayer insulating layer 919 may cover the upper portion of the bonding layer 715 and the first connection electrode CE1 surrounded by the first planarization layer 716. The third interlayer insulating layer 919 may cover a side surface of the first semiconductor layer 121 of the light-emitting element 120, a side surface of the light-emitting layer 122, and a side surface of a part of the second semiconductor layer 123.

The third reflective electrode RE3 is disposed between the third interlayer insulating layer 919 and the first planarization layer 716. The third reflective electrode RE3 may be formed in a majority of the area of the substrate 110 and reflect light, which is emitted from the light-emitting element 120, to the upper portion of the substrate 110. In this case, the third reflective electrode RE3 may be shaped to surround the side surface of the light-emitting element 120 and electrically insulated from the first semiconductor layer 121 of the light-emitting element 120 and the first connection electrode CE1 by the third interlayer insulating layer 919.

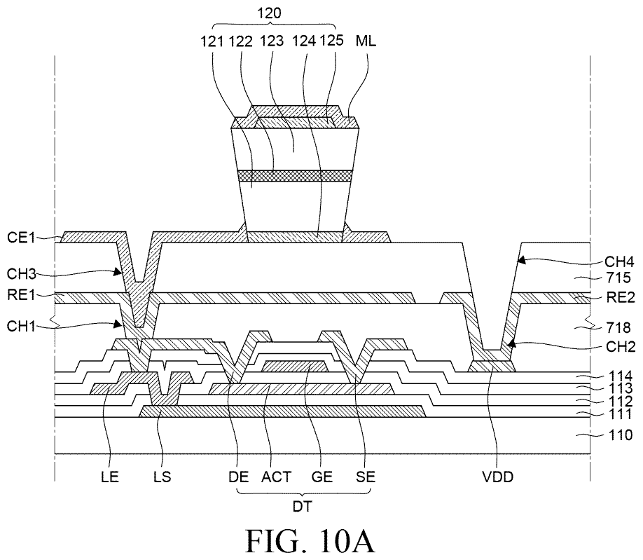

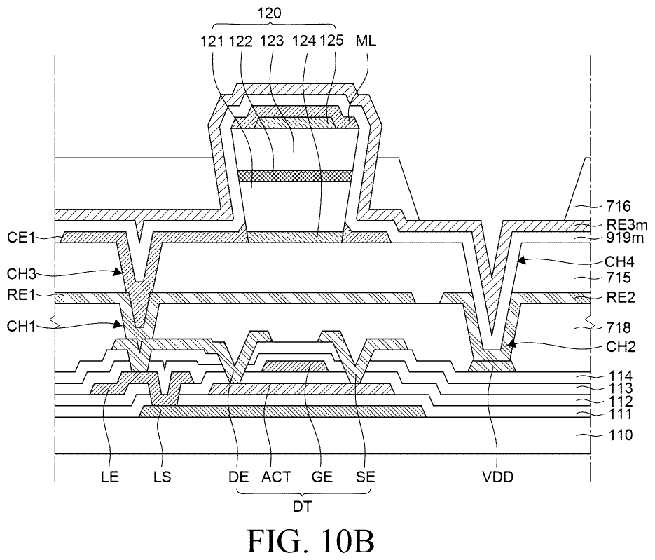

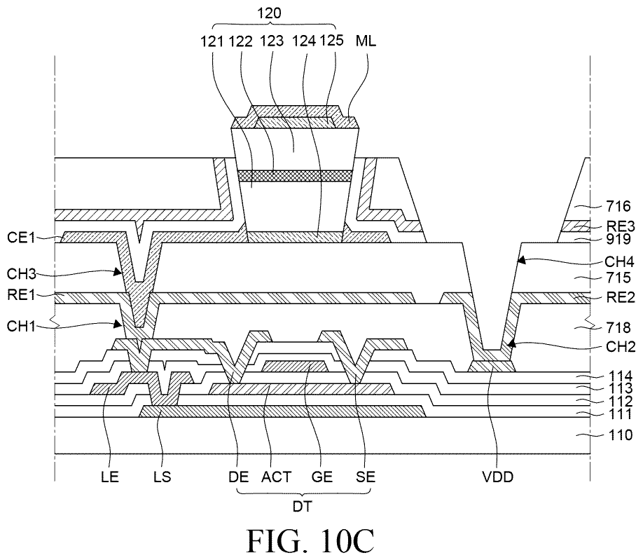

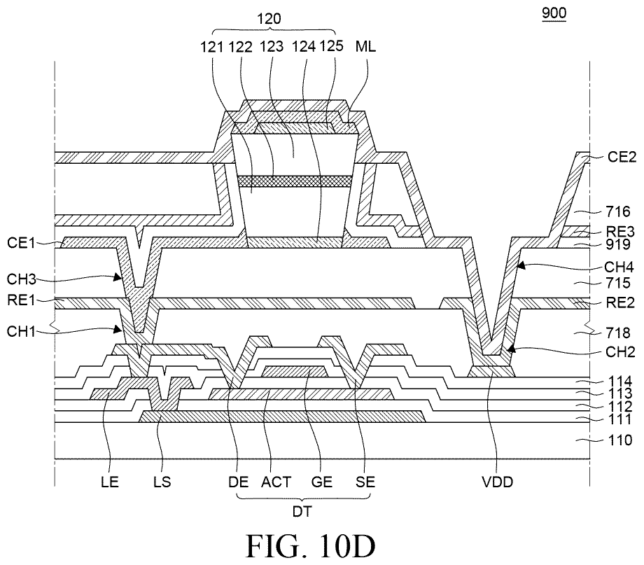

Hereinafter, a method of manufacturing the display device 900 according to still another exemplary embodiment of the present specification will be described with reference to FIGS. 10A to 10D.

FIGS. 10A to 10D are process diagrams for explaining a method of manufacturing the display device according to still another exemplary embodiment of the present specification.

With reference to FIG. 10A, the light-emitting element 120 is transferred onto the bonding layer 715, and the first connection electrode CE1 is formed. As described above with reference to FIGS. 6B and 8A, the first connection electrode CE1 may be formed in a self-alignment manner by the light-emitting element 120 having an inversely tapered shape. The first connection electrode CE1 is disconnected from the metal layer ML that covers the upper portion of the light-emitting element 120. The first connection electrode CE1 may electrically connect only the first semiconductor layer 121 of the light-emitting element 120 to the driving transistor DT and the first reflective electrode RE1.

With reference to FIG. 10B, on the light-emitting element 120 and the first connection electrode CE1, a third interlayer insulating material layer 919m, a third reflective material layer RE3m, and the first planarization layer 716 are formed on the front surface of the substrate 110.

The third interlayer insulating material layer 919m may be formed on the front surface of the substrate 110 so as to cover the first connection electrode CE1 and the light-emitting element 120. The third interlayer insulating material layer 919m may be disposed to cover the first connection electrode CE1 and cover both the side surface and the upper portion of the light-emitting element 120.

On the third interlayer insulating material layer 919m, the third reflective material layer RE3m may be formed on the front surface of the substrate 110. The third reflective material layer RE3m may be disposed to be spaced apart from the light-emitting element 120 and the first connection electrode CE1 by the third interlayer insulating material layer 919m.

On the third reflective material layer RE3m, the first planarization layer 716 is formed on the front surface of the substrate 110. First, the first planarization layer 716 may be formed by forming the first planarization material layer on the third reflective material layer RE3m and etching a part of the first planarization material layer that overlaps the second contact hole CH2 and the fourth contact hole CH4.

In this case, the first planarization layer 716 may be formed at least at a height lower than a height of the upper portion of the light-emitting element 120, e.g., the second electrode 125 of the light-emitting element 120. Therefore, a thickness of the first planarization layer 716 may be adjusted by forming the first planarization material layer on the front surface of the substrate 110 and then additionally performing the ashing process that reduces the overall thickness of the first planarization material layer.

With reference to FIG. 10C, the third interlayer insulating layer 919 and the third reflective electrode RE3 are formed by etching the third interlayer insulating material layer 919m and the third reflective material layer RE3m. The third interlayer insulating layer 919 and the third reflective electrode RE3 may be formed by etching the third interlayer insulating material layer 919m and the third reflective material layer RE3m exposed from the first planarization layer 716.

For example, the first planarization layer 716 has a thickness smaller than a thickness of the light-emitting element 120, such that the third interlayer insulating material layer 919m and the third reflective material layer RE3m, which cover the upper portion of the light-emitting element 120, may be exposed from the first planarization layer 716. Further, the first planarization layer 716 is opened in the second contact hole CH2 and the fourth contact hole CH4, such that the third interlayer insulating material layer 919m and the third reflective material layer RE3m, which overlap the second contact hole CH2 and the fourth contact hole CH4, may be exposed from the first planarization layer 716. Therefore, the third interlayer insulating layer 919 and the third reflective electrode RE3 may be formed by etching the third interlayer insulating material layer 919m and the third reflective material layer RE3m that cover the upper portion of the light-emitting element 120, the second contact hole CH2, and the fourth contact hole CH4.

With reference to FIG. 10D, the second connection electrode CE2 is formed on the first planarization layer 716. The second connection electrode CE2 may be formed on the front surface of the substrate 110 and electrically connected to the second semiconductor layer 123 and the second electrode 125 of the light-emitting element 120 through the metal layer ML. Further, the second connection electrode CE2 may be electrically connected to the second reflective electrode RE2 and the power line VDD through the fourth contact hole CH4.

In this case, a cross-section of the third reflective electrode RE3 may be exposed from the top surface and the side surface of the first planarization layer 716 and adjoin the second connection electrode CE2. That is, the third reflective electrode RE3 may be electrically connected to the second connection electrode CE2. However, because the third reflective electrode RE3 is in a state of being physically separated from the first connection electrode CE1 and the light-emitting element 120 by the third interlayer insulating layer 919, a problem of a short-circuit defect or the like does not occur even though the second connection electrode CE2 is connected to the third reflective electrode RE3.

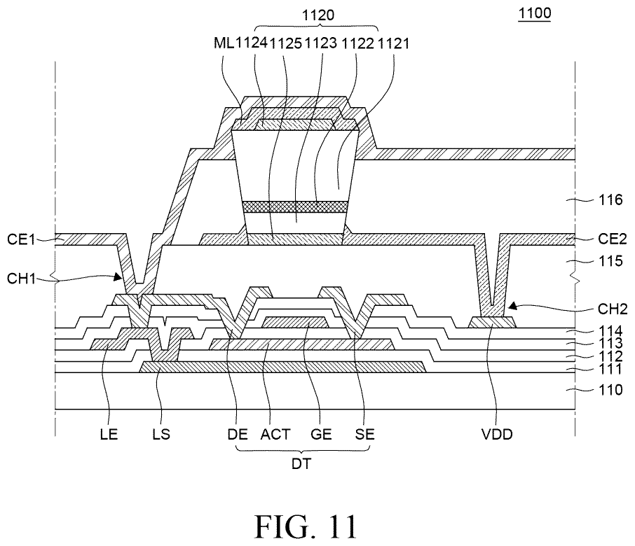

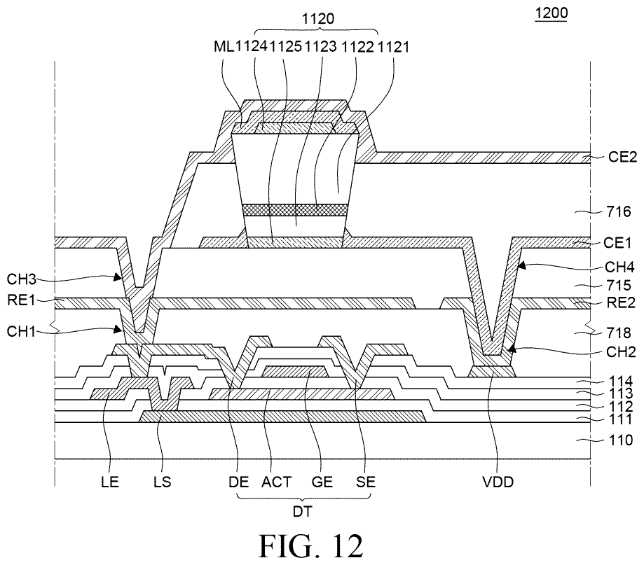

Meanwhile, in the present specification, the configuration has been described in which the display device 900 in FIG. 9 is formed by forming the third interlayer insulating layer 919 and the third reflective electrode RE3 in the display device 700 in FIG. 7. However, the third interlayer insulating layer 919 and the third reflective electrode RE3 may also be applied to the display device 100 in FIGS. 1 to 3 or display devices 1100 and 1200 in FIGS. 11 and 12 to be described below. However, the present disclosure is not limited thereto.

Therefore, in the display device 900 and the method of manufacturing the display device 900 according to still another exemplary embodiment of the present specification, the third reflective electrode RE3 may be formed in a majority of the area of the substrate 110, thereby further improving light extraction efficiency. The third reflective electrode RE3, which is made of an electrically conductive material having excellent reflection performance, may be formed on a majority of the substrate 110. The third reflective electrode RE3 may reflect light, which is emitted from the light-emitting element 120, to the upper portion of the substrate 110, thereby improving light extraction efficiency of the display device 900. In this case, the third reflective electrode RE3 may be disposed to be spaced apart from the first connection electrode CE1 and the first semiconductor layer 121 and the light-emitting layer 122 of the light-emitting element 120 by the third interlayer insulating layer 919. Further, a cross-section of the third reflective electrode RE3, which is exposed from the top surface and the side surface of the first planarization layer 716, may be electrically connected to and adjoin only the second connection electrode CE2. Therefore, the third reflective electrode RE3 electrically connected to the second connection electrode CE2 may be insulated from the first semiconductor layer 121 and the first connection electrode CE1 by the third interlayer insulating layer 919, thereby suppressing a short-circuit defect. Therefore, in the display device 900 and the method of manufacturing the display device 900 according to according to still another exemplary embodiment of the present specification, the third reflective electrode RE3 may be formed to improve light extraction efficiency of the display device 900, and the third interlayer insulating layer 919 may be formed below the third reflective electrode RE3 to suppress a short-circuit defect of the first connection electrode CE1 and the second connection electrode CE2.

FIG. 11 is a cross-sectional view of a display device according to yet another exemplary embodiment of the present specification. FIG. 12 is a cross-sectional view of a display device according to still yet another exemplary embodiment of the present specification. The display device 1100 in FIG. 11 is substantially identical in configuration to the display device 100 in FIGS. 1 to 3, except for a light-emitting element 1120, the first connection electrode CE1, and the second connection electrode CE2. The display device 1200 in FIG. 12 is substantially identical in configuration to the display device 700 in FIG. 7, except for a light-emitting element 1120, the first connection electrode CE1, and the second connection electrode CE2. Therefore, repeated descriptions of the identical components will be omitted.

With reference to FIG. 11, the light-emitting element 1120 includes a first semiconductor layer 1121, a light-emitting layer 1122, a second semiconductor layer 1123, a first electrode 1124, and a second electrode 1125. The second semiconductor layer 1123 is disposed on the second electrode 1125. The light-emitting layer 1122, the first semiconductor layer 1121, and the first electrode 1124 are sequentially disposed on the second semiconductor layer 1123.

The light-emitting element 1120 has an inversely tapered shape. The light-emitting element 1120 may have a shape having a width that increases from below to above. For example, an area of a top surface of the second semiconductor layer 1123 disposed below the first semiconductor layer 1121 may be smaller than an area of a top surface of the first semiconductor layer 1121.

The second connection electrode CE2 is disposed on the bonding layer 115. The second connection electrode CE2 may be disposed between the bonding layer 115 and the first planarization layer 116. The second connection electrode CE2 may be connected to the power line VDD through the second contact hole CH2 while being disposed to surround a lower portion of the light-emitting element 1120 adjacent to the bonding layer 115, i.e., surround a side surface of the second electrode 1125 and a side surface of the second semiconductor layer 1123. Therefore, the second semiconductor layer 1123 and the second electrode 1125 may be electrically connected to the power line VDD through the second connection electrode CE2.

In this case, the metal layer ML may be present on the upper portion of the light-emitting element 1120 and formed together with the second connection electrode CE2 when the second connection electrode CE2 is formed. In case that the metallic material layer is formed to cover the light-emitting element 1120 after the light-emitting element 1120 is transferred onto the bonding layer 115, the metallic material layer may be disconnected from the second connection electrode CE2 formed on the bonding layer 115 and the metal layer ML, which covers the upper portion of the light-emitting element 1120, by the light-emitting element 1120 having an inversely tapered shape.

The first planarization layer 116 is disposed to cover the light-emitting element 1120 and the second connection electrode CE2. The first planarization layer 116 may be disposed to at least cover the light-emitting layer 1122 and the second semiconductor layer 1123 of the light-emitting element 1120 and insulate the second connection electrode CE2 from the first connection electrode CE1, which is formed subsequently, by completely covering the second connection electrode CE2. The first planarization layer 116 may be patterned in the area that overlaps the first contact hole CH1. The first contact hole CH1 may be exposed from the first planarization layer 116.

The first connection electrode CE1 is disposed on the first planarization layer 116 and the light-emitting element 1120. The first connection electrode CE1 may be electrically connected to the metal layer ML, the first electrode 1124, and the first semiconductor layer 1121 while covering the upper portion of the light-emitting element 1120. Further, the first connection electrode CE1 may be formed on the first contact hole CH1 exposed from the first planarization layer 116. The first connection electrode CE1 may be electrically connected to the drain electrode DE of the driving transistor DT.

With reference to FIG. 12, like the display device 1100 in FIG. 11, in the display device 1200 in FIG. 12, the second electrode 1125 of the light-emitting element 1120 may be disposed at a lowermost side, and the first electrode 1124 and disposed at an uppermost side. Further, the light-emitting element 1120 has an inversely tapered shape, such that the top surface of the first semiconductor layer 1121 may have a larger area than the top surface of the second semiconductor layer 1123.

The second connection electrode CE2 may be disposed between the bonding layer 715 and the first planarization layer 716. The second connection electrode CE2 may be disposed to surround the lower portion of the light-emitting element 1120, i.e., the side surface of the second electrode 1125 and the side surface of the second semiconductor layer 1123. Further, the second connection electrode CE2 may be electrically connected to the second reflective electrode RE2 and the power line VDD through the fourth contact hole CH4. Therefore, the second connection electrode CE2 may electrically connect the second semiconductor layer 1123 and the second electrode 1125 to the second reflective electrode RE2 and the power line VDD.

The first planarization layer 716 is disposed to cover the light-emitting element 1120 and the second connection electrode CE2. The first planarization layer 716 may be patterned in the area that overlaps the third contact hole CH3. The third contact hole CH3 may be exposed from the first planarization layer 716.

The first connection electrode CE1 is disposed on the first planarization layer 716 and the light-emitting element 1120. The first connection electrode CE1 may be electrically connected to the metal layer ML, the first electrode 1124, and the first semiconductor layer 1121 while covering the upper portion of the light-emitting element 1120. Further, the first connection electrode CE1 may be formed on the third contact hole CH3 exposed from the first planarization layer 716. The first connection electrode CE1 may be electrically connected to the first reflective electrode RE1 and the drain electrode DE of the driving transistor DT.

Therefore, in the display devices 100, 700, 900, 1100, and 1200 according to various exemplary embodiments of the present specification, the light-emitting elements 120 and 1120, the driving transistor DT, and the power line VDD may be electrically connected regardless of the transfer directions of the light-emitting elements 120 and 1120. Like the display devices 100, 700, and 900 in FIGS. 1, 7, and 9, in case that the light-emitting element 120 is transferred to be disposed below the first semiconductor layer 121, the metallic material layer, which constitutes the first connection electrode CE1, may be formed to overlap the light-emitting element 120 and the drain electrode DE, such that the first connection electrode CE1 may be formed. Further, a part of each of the first planarization layers 116 and 716 is removed from the area that overlaps the power line VDD, such that the second connection electrode CE2 and the second electrode 125 and the second semiconductor layer 123 of the light-emitting element 120 formed on each of the first planarization layers 116 and 716 may be electrically connected. Further, like the display devices 1100 and 1200 in FIGS. 11 and 12, in case that the light-emitting element 1120 is transferred to be disposed below the second semiconductor layer 1123, the metallic material layer, which constitutes the second connection electrode CE2, may be formed to overlap the light-emitting element 1120 and the power line VDD, such that the second connection electrode CE2 may be formed. Further, a part of each of the first planarization layers 116 and 716 is removed from the area that overlaps the drain electrode DE, the first connection electrode CE1 and the first electrode 1124 and the first semiconductor layer 1121 of the light-emitting element 1120 formed on each of the first planarization layers 116 and 716 may be electrically connected. Therefore, even though the transfer directions of the light-emitting elements 120 and 1120 are changed reversely, the first connection electrode CE1 and the second connection electrode CE2 may be easily formed by simply changing the area in which the metallic material layer is formed and changing the area in which the first planarization layers 116 and 716 are patterned.

The exemplary embodiments of the present disclosure can also be described as follows:

According to an aspect of the present disclosure, there is provided a display device. The display device includes a substrate on which a plurality of sub-pixels is defined, a light-emitting element disposed on each of the plurality of sub-pixels and having an inversely tapered shape, a first connection electrode configured to surround a side surface of a lower portion of the light-emitting element, a second connection electrode configured to cover an upper portion of the light-emitting element, and a first planarization layer disposed between the first connection electrode and the second connection electrode.

The light-emitting element may include a first semiconductor layer electrically connected to the first connection electrode, a second semiconductor layer electrically connected to the second connection electrode, and a light-emitting layer disposed between the first semiconductor layer and the second semiconductor layer.

The light-emitting element may be configured such that the light-emitting layer and the second semiconductor layer are disposed on the first semiconductor layer, an area of a top surface of the first semiconductor layer may be smaller than an area of a top surface of the second semiconductor layer, and a top surface of the first planarization layer may be disposed at a height equal to or lower than a height of the top surface of the second semiconductor layer.

The display device may further include a metal layer disposed between the second semiconductor layer and the second connection electrode of the light-emitting element, the metal layer may be made of the same material as the first connection electrode.

The second connection electrode may be electrically connected to the second semiconductor layer through the metal layer.

The display device may further include a bonding layer disposed below the light-emitting element and the first connection electrode, a driving transistor disposed between the substrate and the bonding layer, and a power line disposed between the substrate and the bonding layer, the first connection electrode may electrically connect the driving transistor and the first semiconductor layer through a contact hole of the bonding layer, and the second connection electrode may electrically connect the power line and the second semiconductor layer through a contact hole of the bonding layer.

The display device may further include a passivation layer disposed between the driving transistor and the power line and the bonding layer, a first reflective electrode disposed between the passivation layer and the bonding layer and electrically connected to the driving transistor and the first connection electrode, and a second reflective electrode disposed on the passivation layer and the bonding layer and electrically connected to the power line and the second connection electrode.

The display device may further include an interlayer insulating layer disposed on the first connection electrode and disposed to surround the first semiconductor layer of the light-emitting element, and a third reflective electrode disposed between the interlayer insulating layer and the first planarization layer, the third reflective electrode may be separated from the first semiconductor layer and the first connection electrode by the interlayer insulating layer.

A cross-section of the third reflective electrode may be exposed from a top surface and a side surface of the first planarization layer, and the exposed cross-section of the third reflective electrode may adjoin the second connection electrode.

The light-emitting element may be configured such that the light-emitting layer and the first semiconductor layer are disposed on the second semiconductor layer, an area of a top surface of the second semiconductor layer may be smaller than an area of a top surface of the first semiconductor layer, and a top surface of the first planarization layer may be disposed at a height equal to or lower than a height of a top surface of the first semiconductor layer.

According to an aspect of the present disclosure, there is provided a method of manufacturing a display device. The method includes transferring a light-emitting element having an inversely tapered shape onto a bonding layer, forming a first connection electrode by forming a metallic material layer on the light-emitting element, forming a first planarization layer on the light-emitting element and the first connection electrode, the first planarization layer having a larger thickness than a first semiconductor layer of the light-emitting element, and forming a second connection electrode on the first planarization layer and the light-emitting element.

The forming of the first connection electrode may be performed such that the metallic material layer is disconnected by the light-emitting element having an inversely tapered shape and divided into a metal layer configured to cover an upper portion of the light-emitting element, and the first connection electrode configured to surround a lower portion of the light-emitting element while covering the bonding layer.

The forming of the second connection electrode may include forming an electrically conductive material layer on the first planarization layer and the light-emitting element, and the second connection electrode may be electrically connected to a second semiconductor layer at an upper side of the light-emitting element exposed from the first planarization layer.

The second connection electrode may be formed to adjoin the metal layer, and the metal layer may electrically connect the second connection electrode and the second semiconductor layer.

The method may further include forming first reflective electrode and second reflective electrode spaced apart from each other on a substrate, and forming the bonding layer on the first reflective electrode and the second reflective electrode.

The first connection electrode may be electrically connected to the first reflective electrode, and the second connection electrode may be electrically connected to the second reflective electrode.

The method may further include forming an interlayer insulating material layer, which covers the first connection electrode and the light-emitting element, before the first planarization layer is formed, forming a third reflective material layer on the interlayer insulating material layer, forming the first planarization layer on the third reflective material layer, and forming an interlayer insulating layer and a third reflective electrode by etching the interlayer insulating material layer and the third reflective material layer exposed from the first planarization layer, the third reflective electrode may be disposed between the interlayer insulating layer and the first planarization layer and electrically insulated from the first connection electrode, and the third reflective electrode may have a cross-section exposed from the first planarization layer and is electrically connected to the second connection electrode.

It will be apparent to those skilled in the art that various modifications and variations can be made in the display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate on which a plurality of sub-pixels is defined;
a light-emitting element disposed on each of the plurality of sub-pixels and having an inversely tapered shape;
a first connection electrode configured to surround a side surface of a lower portion of the light-emitting element;
a second connection electrode configured to cover an upper portion of the light-emitting element; and
a first planarization layer disposed between the first connection electrode and the second connection electrode.

2. The display device of claim 1, wherein the light-emitting element comprises:
a first semiconductor layer electrically connected to the first connection electrode;
a second semiconductor layer electrically connected to the second connection electrode; and
a light-emitting layer disposed between the first semiconductor layer and the second semiconductor layer.

3. The display device of claim 2, wherein the light-emitting element is configured such that the light-emitting layer and the second semiconductor layer are disposed on the first semiconductor layer,
wherein an area of a top surface of the first semiconductor layer is smaller than an area of a top surface of the second semiconductor layer, and
wherein a top surface of the first planarization layer is disposed at a height equal to or lower than a height of the top surface of the second semiconductor layer.

4. The display device of claim 3, further comprising:
a metal layer disposed between the second semiconductor layer and the second connection electrode of the light-emitting element,
wherein the metal layer is made of the same material as the first connection electrode.

5. The display device of claim 4, wherein the second connection electrode is electrically connected to the second semiconductor layer through the metal layer.

6. The display device of claim 4, further comprising:
a bonding layer disposed below the light-emitting element and the first connection electrode;
a driving transistor disposed between the substrate and the bonding layer; and
a power line disposed between the substrate and the bonding layer,
wherein the first connection electrode electrically connects the driving transistor and the first semiconductor layer through a contact hole of the bonding layer, and
wherein the second connection electrode electrically connects the power line and the second semiconductor layer through a contact hole of the bonding layer.

7. The display device of claim 6, further comprising:
a passivation layer disposed between the driving transistor and the power line and the bonding layer;
a first reflective electrode disposed between the passivation layer and the bonding layer and electrically connected to the driving transistor and the first connection electrode; and
a second reflective electrode disposed on the passivation layer and the bonding layer and electrically connected to the power line and the second connection electrode.

8. The display device of claim 3, further comprising:
an interlayer insulating layer disposed on the first connection electrode and disposed to surround the first semiconductor layer of the light-emitting element; and
a third reflective electrode disposed between the interlayer insulating layer and the first planarization layer,
wherein the third reflective electrode is separated from the first semiconductor layer and the first connection electrode by the interlayer insulating layer.

9. The display device of claim 8, wherein a cross-section of the third reflective electrode is exposed from a top surface and a side surface of the first planarization layer, and
wherein the exposed cross-section of the third reflective electrode adjoins the second connection electrode.

10. The display device of claim 2, wherein the light-emitting element is configured such that the light-emitting layer and the first semiconductor layer are disposed on the second semiconductor layer,
wherein an area of a top surface of the second semiconductor layer is smaller than an area of a top surface of the first semiconductor layer, and
wherein a top surface of the first planarization layer is disposed at a height equal to or lower than a height of a top surface of the first semiconductor layer.

11. A method of manufacturing a display device, the method comprising:
transferring a light-emitting element having an inversely tapered shape onto a bonding layer;
forming a first connection electrode by forming a metallic material layer on the light-emitting element;
forming a first planarization layer on the light-emitting element and the first connection electrode, the first planarization layer having a larger thickness than a first semiconductor layer of the light-emitting element; and
forming a second connection electrode on the first planarization layer and the light-emitting element.

12. The method of claim 11, wherein the forming of the first connection electrode is performed such that the metallic material layer is disconnected by the light-emitting element having an inversely tapered shape and divided into a metal layer configured to cover an upper portion of the light-emitting element, and the first connection electrode configured to surround a lower portion of the light-emitting element while covering the bonding layer.

13. The method of claim 12, wherein the forming of the second connection electrode comprises forming an electrically conductive material layer on the first planarization layer and the light-emitting element, and
wherein the second connection electrode is electrically connected to a second semiconductor layer at an upper side of the light-emitting element exposed from the first planarization layer.

14. The method of claim 13, wherein the second connection electrode is formed to adjoin the metal layer, and
wherein the metal layer electrically connects the second connection electrode and the second semiconductor layer.

15. The method of claim 11, further comprising:
forming first reflective electrode and second reflective electrode spaced apart from each other on a substrate; and
forming the bonding layer on the first reflective electrode and the second reflective electrode.

16. The method of claim 15, wherein the first connection electrode is electrically connected to the first reflective electrode, and the second connection electrode is electrically connected to the second reflective electrode.

17. The method of claim 15, further comprising:
forming an interlayer insulating material layer, which covers the first connection electrode and the light-emitting element, before the first planarization layer is formed;
forming a third reflective material layer on the interlayer insulating material layer;
forming the first planarization layer on the third reflective material layer; and
forming an interlayer insulating layer and a third reflective electrode by etching the interlayer insulating material layer and the third reflective material layer exposed from the first planarization layer,
wherein the third reflective electrode is disposed between the interlayer insulating layer and the first planarization layer and electrically insulated from the first connection electrode, and
wherein the third reflective electrode has a cross-section exposed from the first planarization layer and is electrically connected to the second connection electrode.
